(19) United States
(12) Patent Application Publication
(10) Pub. No.: US 2023/0273347 A1
(43) Pub. Date: Aug. 31, 2023

(54) TRANSPARENT FILM WITH ENHANCED DURABILITY

(71) Applicant: MSWAY Technology Co., Ltd., Seoul (KR)

(72) Inventors: Min Soo LEE, Seoul (KR); Jong Chun PARK, Anyang-si (KR); Su Hyun JUNG, Gumi-si (KR); Jeong Hyeob HAN, Gumi-si (KR)

(73) Assignee: MSWAY Technology Co., Ltd., Seoul (KR)

(21) Appl. No.: 17/622,751

(22) PCT Filed: Nov. 20, 2020
(86) PCT No.: PCT/KR2020/016536

§ 371 Date: Dec. 24, 2021

(30) Foreign Application Priority Data
Nov. 19, 2020 (KR) 10-2020-0155206

(51) Int. Cl. G02B 1/14; C08J 7/06; C08J 7/04; C23C 14/06; C23C 14/34; C23C 14/08

(52) U.S. Cl. CPC G02B 1/14; C08J 7/06; C08J 7/0423; C23C 14/0641; C23C 14/0652; C23C 14/34; C23C 14/087; C08J 2333/12; C08J 2333/14

(57) ABSTRACT

A transparent film with enhanced durability is disclosed. The present invention provides a transparent film with enhanced durability including: a base layer; a first inorganic material layer stacked on a first surface of the base layer; a metal layer stacked on a first surface of the first inorganic material layer; a second inorganic material layer stacked on a a first surface of the metal layer; and a passivation layer configured to include a plurality of organic material layers stacked on a first surface of the second inorganic material layer.

### CROSS-REFERENCE TO RELATED APPLICATION

This application claims priority to and benefits of Korean Patent Application No. 10-2020-0155206 filed in the Korean Intellectual Property Office on Nov. 19, 2020, the entire contents of which are incorporated herein by reference.

### BACKGROUND OF THE INVENTION

### (a) Field of the Invention

The present invention relates to a transparent film with enhanced durability.

This work was supported by the Technology development Program (S2842434) funded by the Ministry of SMEs and Startups (MSS, Korea)

### (b) Description of the Related Art

Recently, many high-resolution display products of 8 K or higher, including LED TVs, have been released. However, as the resolution increases, density of pixels in a single area increases. As the density of pixels increases, a number of TFTs also increases and heat is generated naturally.

An LED TV generates a lot of heat not only from a TFT but also from an LED itself, which generates more heat and electromagnetic waves than an LCD or an OLED, and the need to block the heat and the electromagnetic waves at a same time is increasing.

In the case of a conventional ITO electrode, it is widely used as an electrode material having excellent electrical conductivity and high light transmittance. However, a thermal blocking characteristic and electromagnetic waves shielding performance are significantly lowered, making it impossible to use.

Although silver nanowire (AgNW) has high transparency, it has a chronic problem in that it cannot overcome the problems of heat blocking ability and reliability.

Numerous studies have been conducted on silver (Ag) or alloys of silver, but there has been no solution that has secured stability of silver so far.

Nevertheless, silver has superior electromagnetic and heat shielding and blocking characteristics than any other material, so research is continuing to secure durability of silver.

In particular, considering that an Ag layer formed as a thin film has much lower stability than a thick film, it is an important technical task to secure stability of the silver thin film.

On the other hand, a plastic film used as a display substrate has an inferior light transmission characteristic compared to a glass substrate. Accordingly, it is not an easy task to improve an optical characteristic by using a plastic substrate, and it is important to increase even fine transmittance as much as possible.

Therefore, it is necessary to apply an anti-reflection effect to the film and simultaneously realize a gas permeation barrier film effect. Permeability to oxygen or moisture is sometimes explained by a pinhole model, and for this reason, a multi-layered structure has a remarkable effect in preventing penetration of oxygen, moisture, etc. due to separation in terms of a distance of pinholes between layers.

However, there was a limitation that an inorganic protective layer alone could not completely prevent penetration of moisture and gas.

The above information disclosed in this Background section is only for enhancement of understanding of the background of the invention, and therefore, it may contain information that does not form the prior art that is already known in this country to a person of ordinary skill in the art.

### SUMMARY OF THE INVENTION

The present invention has been made in an effort to provide a transparent film with enhanced durability, capable of simultaneously implementing heat blocking and electromagnetic blocking by securing durability by preventing oxidation of a silver thin film layer.

An exemplary embodiment of the present invention provides a transparent film with enhanced durability, including: a base layer; a first inorganic material layer stacked on a first surface of the base layer; a metal layer stacked on a first surface of the first inorganic material layer; a second inorganic material layer stacked on a first surface of the metal layer; and a passivation layer configured to include a plurality of organic material layers stacked on a first surface of the second inorganic material layer.

In an exemplary embodiment of the present invention, it may further include a hard coating layer disposed on opposite surfaces of the base layer.

In an exemplary embodiment of the present invention, it may further include a refractive index matching layer disposed between the base layer and the first inorganic material layer and between the second inorganic material layer and the passivation layer, to reinforce a refractive index.

In an exemplary embodiment of the present invention, the passivation layer may include: a first passivation layer configured to include a first organic material; a second passivation layer configured to include a second organic material; a third passivation layer configured to include a third organic material; and a fourth passivation layer configured to include a fourth an organic material.

In an exemplary embodiment of the present invention, the metal layer may include silver (Ag), and the first inorganic material layer and the second inorganic material layer may include a copper oxide (CuOₓ).

In an exemplary embodiment of the present invention, the metal layer may include silver (Ag), and the first inorganic material layer and the second inorganic material layer may include a copper nitride (CuNₓ).

The present invention has an effect of preventing oxidation of a silver thin film layer by compounding organic and inorganic layers into multiple layers.

The present invention has the effect of providing a transparent film with enhanced durability in which high heat blocking and electromagnetic blocking performances are realized as a result of the enhanced durability of the silver thin film layer.

### BRIEF DESCRIPTION OF THE DRAWINGS

FIG. 1 illustrates a transparent film with enhanced durability according to an exemplary embodiment of the present invention.

FIG. 2 illustrates an experimental result measuring transmittance depending on a wavelength of a transparent film with enhanced durability according to an exemplary embodiment of the present invention.

FIG. 3A and FIG. 3B illustrate photographs comparing before and after a reliability test of Comparative Example 1.

FIG. 4A and FIG. 4B illustrate photographs comparing before and after a reliability test of Comparative Example 2.

FIG. 5A and FIG. 5B illustrate photographs comparing before and after a reliability test of an example of the present invention.

FIG. 6A and FIG. 6B illustrate measurement results of a water vapor transmission rate of a transparent film with enhanced durability over time according to an example of the present invention.

FIG. 7 illustrates a level of radio interference noise depending on a frequency of a transparent film with enhanced durability according to an example of the present invention.

FIG. 8A, FIG. 8B, and FIG. 8C illustrate infrared photographs for evaluating heat shielding performance of a transparent film with enhanced durability according to an example and the comparative examples of the present invention.

### DETAILED DESCRIPTION OF THE EMBODIMENTS

The present invention is intended to illustrate the bars, reference to specific embodiments which may have a number of embodiments can be applied to various changes and describes them in detail from the following detailed description. This, However, is by no means to restrict the invention to the specific embodiments, it is to be understood as embracing all included in the spirit and scope of the present invention changes, equivalents and substitutes.

In the following description of the present invention, when it is determined that a detailed description of known techniques that may obscure the subject matter of the present invention, a detailed description thereof will be omitted.

Hereinafter, an exemplary embodiment of the present invention will be described in detail with reference to accompanying drawings.

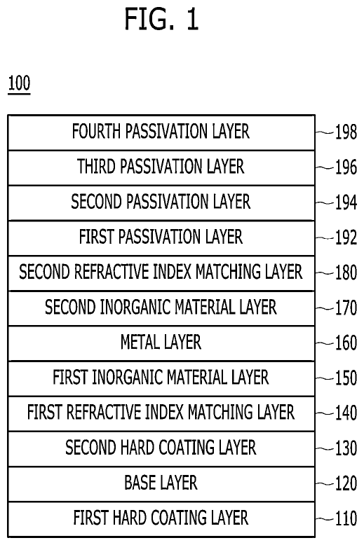

FIG. 1 illustrates a transparent film 100 with enhanced durability according to an exemplary embodiment of the present invention.

Referring to FIG. 1, the transparent film 100 with enhanced durability according to the embodiment of the present invention includes a first hard coating layer 110, a base layer 120, a second hard coating layer 130, and a first refractive index matching layer 140, a first inorganic material layer 150, a metal layer 160, second inorganic material layer 170, a second refractive index matching layer 180, a first passivation layer 192, a second passivation layer 194, a third passivation layer 196, and a fourth passivation layer 198.

The first hard coating layer 110 and the second hard coating layer 130 are transparent films of high hardness, and may be provided to secure transmission and strength. The first hard coating layer 110 and the second hard coating layer 130 may be used for refractive index matching with other substrates while ensuring high hardness and wear resistance characteristics. In addition, the second hard coating layer 130 also improves interlayer adhesion when an inorganic layer is deposited thereon.

Refractive indexes of the first hard coating layer 110 and the second hard coating layer 130 are preferably selected to be relatively low.

The first hard coating layer 110 and the second hard coating layer 130 may be manufactured by using a manufacturing method of a hard coating film, which is performed by a bar coating method, a knife coating method, a roll coating method, a blade coating method, a die coating method, a micro gravure coating method, a comma coating method, a slot die coating method, a lip coating method, or a solution casting method.

The base layer 120 may be stacked on the first hard coating layer 110, and the second hard coating layer 130 may be stacked on the base layer 120 again.

The base layer 120 may include an inorganic material or an organic material. The inorganic material may be any one or a combination of glass, quartz, Al₂O₃, SiC, Si, GaAs, and InP, but the present invention is not limited thereto. The organic material may be selected from among Kepton foil, polyimide (PI), polyethersulfone (PES), polyacrylate (PAR), polyetherimide (PEI), polyethylene naphthalate (PEN), polyethyleneterephthalate (PET), polyphenylene sulfide (PPS), polyarylate (polyarylate), polycarbonate (PC), cellulose triacetate (CTA), and cellulose acetate propionate (CAP), but the present invention is not limited thereto.

In an exemplary embodiment of the present invention, the base layer 120 may be made of polyethylene terephthalate (PET) used for optics.

Since the base layer 120 is prone to curling due to a thickness of the passivation layers 192, 194, 196, and 198 to be formed of an organic material, it may be preferable to form a thickness of at least 100 μm.

The second hard coating layer 130 may be stacked on the base layer 120.

The first refractive index matching layer 140 may be stacked on the second hard coating layer 130.

The first refractive index matching layer 140 may include an insulating material having a refractive index that is different from that of layers stacked thereon.

The first refractive index matching layer 140 may be preferably made of a material having a large refractive index of 2.0 or more. As a ceramic material used for refractive index matching, TiOₓ, Nb₂Oₓ, or the like is used. The first refractive index matching layer 140 may include a metal oxide, and the metal oxide may include any type of metal oxide having an amphiphilic property. For example, examples thereof may include one or more selected from among a titanium sub-oxide (TiOx), a titanium oxide (TiO₂), a zinc oxide (ZnO), a tungsten oxide (W₂O₃, WO₂, and WO₃), a molybdenum oxide (MoO₂ and MoO₃), a molybdenum sub-oxide (MoOX), and combinations thereof.

The first refractive index matching layer 140 may preferably include a zinc oxide (ZnO) in that it has excellent transmittance, electrical conductivity, and durability against plasma in infrared and visible ray regions, it can be processed at low temperatures, and a raw material price thereof is low.

The first an inorganic material layer 150 may be stacked on the first refractive index matching layer 140. The metal layer 160 may be stacked on the first inorganic material layer 150, and the second inorganic material layer 170 may be stacked on another surface of the metal layer 160. With this structure, the metal layer 160 can be surrounded by two inorganic material layers.

For a transparent film containing silver (Ag) as a metal layer, during a reliability test, silver (Ag) elements may diffuse into the interface to self-generate a new diffusion barrier or specific resistance due to the remaining alloying elements in the silver (Ag) thin film may increase, and thus measures were needed to prevent such problems.

The first inorganic material layer 150 and the second inorganic material layer 170 are configured to function as a thermally or chemically stable diffusion barrier layer. In order to function as a diffusion barrier of silver (Ag), it may be preferable that the first inorganic material layer 150 and the second inorganic material layer 170 include transition metals such as Cu and Ti having low mutual solubility with silver (Ag).

The first inorganic material layer 150 and the second inorganic material layer 170 may be formed as a CuNₓ or SiNₓ thin film deposited using sputtering. Herein, x is used to indicate that there is no fixed or known amount of nitrogen. This is because even though nitrogen is supplied to a metal, when manufacturing a metal nitride, an exact bonding ratio may not be known.

The first an inorganic material layer 150 and the second an inorganic material layer 170 have improved passivation characteristics as their deposition thickness increases. The SiNx thin film formed by the dry oxidation method exhibited about 20 times or more excellent passivation characteristics because it had a denser interfacial structure than that formed by the wet oxidation method.

[Table 1] shows comparison of performances depending on materials of the first inorganic material layer 150 and the second inorganic material layer 170.

TABLE 1

| | | | | | | | Sheet |
|---|---|---|---|---|---|---|---|
| Struc- | Measure- | | | | | 550 | resistance |
| ture | ment mode | L* | a* | b* | Y | nm | (Ω/sq) |
| CuOx/Ag/ | Transmission | 93.98 | −0.84 | 1.36 | 85.22 | 85.24 | 10.94 |
| CuOx | Reflection | 25.74 | −0.95 | −4.68 | 4.66 | 4.82 | |
| CuNx/Ag/ | Transmission | 93.16 | −1.16 | 0.7 | 83.33 | 83.58 | 11.66 |
| CuNx | Reflection | 24.6 | 1.68 | −2.3 | 4.29 | 4.34 | |

In [Table 1], a* and b* are coordinates defined in CIE (International Commission on Illumination) LAB color space, a* indicates a degree of red and green, and b* indicates a degree of yellow and blue

Y represents luminance, L* represents brightness, and transmittance was measured at 550 nm.

In the present invention, a copper oxide and a copper nitride were compared and analyzed, and as a result, the copper oxide was advantageous in terms of an increase in transmittance, but it was found that nitride was excellent in passivation characteristics.

The first inorganic material layer 150 and the second inorganic material layer 170 may be formed in a range of 5 nm to 10 nm in consideration of transmission.

As a metal forming the metal layer 160, the metal layer 160 may include a conductive material such as APC, Cu, a Cu alloy, Ag, an Ag alloy, Mo/Ag, or Mo/APC.

Preferably, in an exemplary embodiment of the present invention, the metal layer 160 may include silver (Ag).

As the thickness of the metal layer 160 increases, the thin film of the metal layer 160 has reduced transmission due to absorption or scattering, it may be formed to a thickness of about 10 nm when the multi-layered thin film is formed.

The second refractive index matching layer 180 may be stacked on the second inorganic material layer 170.

A material for the second refractive index matching layer 180 may be a material having a refractive index that is different from that of the first refractive index matching layer 140.

The second refractive index matching layer 180 may be preferably made of a material having a large refractive index of 2.0 or more. As a ceramic material used for the second refractive index matching layer 180, TiOₓ, Nb₂Oₓ, or the like is used. The second refractive index matching layer 180 may include a metal oxide, and the metal oxide may include any type of metal oxide having an amphiphilic property. For example, examples thereof may include one or more selected from among a titanium sub-oxide (TiOx), a titanium oxide (TiO₂), a zinc oxide (ZnO), a tungsten oxide (W₂O₃, WO₂, and WO₃), a molybdenum oxide (MoO₂ and MoO₃), a molybdenum sub-oxide (MoOX), and combinations thereof. Preferably, the second refractive index matching layer 180 may include zinc oxide (ZnO) in that it has excellent transmittance, electrical conductivity, and durability against plasma in infrared and visible ray regions, it can be processed at low temperatures, and a raw material price thereof is low.

The first passivation layer 192 may be stacked on the second refractive index matching layer 180.

The first passivation layer 192 may include a first organic material. The first passivation layer 192 may complement other stacked thin films to prevent oxidation of the metal layer 160, that is, a silver thin film, thereby enhancing durability of the transparent heat shielding film.

The first passivation layer 192 may be formed of a material having a different refractive index while having adhesion with the second refractive index matching layer 180. The first passivation layer 192 may be formed of a polymer having a lower refractive index than that of the second refractive index matching layer 180, and may be formed of a material having a refractive index of 1.5.

The first passivation layer 192 may be formed of any one selected from among polyvinylpyrrolidone (PVP), polycarbonate (PC), poly(methyl methacrylate) (PMMA), polystyrene (PS), polyvinyl alcohol (PVA), and cellulose.

The first passivation layer 192 may be formed to have a thickness of 30 nm to 300 nm by using a solution process. When the first passivation layer 192 is formed to be less than 30 nm, there may be difficulties during solution coating, and when it is formed to be more than 300 nm, it may be difficult to attach to the refractive index matching layer. In addition, when it is out of the corresponding range, the transmission may be lowered.

The second passivation layer 194 may be stacked on the first passivation layer 192.

The second passivation layer 194 may include a second organic material. The second passivation layer 194 may complement other stacked thin films to prevent oxidation of the metal layer 160, that is, a silver thin film, thereby enhancing durability of the transparent heat shielding film.

The second passivation layer 194 may be formed of a material having an adhesion with the first passivation layer 192 and having a difference in refractive index.

The second passivation layer 194 may be formed of a material having a refractive index of 1.55.

The second passivation layer 194 may be formed by including a polymer selected from any one group of urethane acrylate-based, silicone acrylate-based, and epoxy acrylate-based polymers.

The second passivation layer 194 may preferably be a polymer that is curable. The second passivation layer 194 may also be formed by applying an additive such as a resin additive or an inorganic filler to improve performance. This additive may serve to increase spreadability or to adjust the refractive index to a desired degree.

The second passivation layer 194 may be formed to have a thickness of 50 nm to 300 nm by using a solution process. In addition, when it is out of the corresponding range, the transmission may be lowered.

The third passivation layer 196 may be stacked on the second passivation layer 194.

The third passivation layer 196 may include a third organic material. The third passivation layer 196 may complement other stacked thin films to prevent oxidation of the metal layer 160, that is, a silver thin film, thereby enhancing durability of the transparent heat shielding film.

The third passivation layer 196 may be formed of a material having an adhesion with the second passivation layer 194 and having a difference in refractive index. The third passivation layer 196 may be formed of a polymer having a lower refractive index than that of the second passivation layer 194, and may be formed of a material having a refractive index of 1.5.

The third passivation layer 196 may be formed of any one selected from among polyvinylpyrrolidone (PVP), polycarbonate (PC), poly(methyl methacrylate) (PMMA), polystyrene (PS), polyvinyl alcohol (PVA), and cellulose.

The third passivation layer 196 may be formed to have a thickness of 30 nm to 300 nm by using a solution process.

The fourth passivation layer 198 may be stacked on the third passivation layer 196.

The fourth passivation layer 198 may include a fourth organic material. The fourth passivation layer 198 may complement other stacked thin films to prevent oxidation of the metal layer 160, that is, a silver thin film, thereby enhancing durability of the transparent heat shielding film.

The fourth passivation layer 198 may be formed of a material having an adhesion with the third passivation layer 196 and having a difference in refractive index.

The fourth passivation layer 198 may be formed of a material having a refractive index of 1.55.

The fourth passivation layer 198 may be formed by including a polymer selected from any one group of urethane acrylate-based, silicone acrylate-based, and epoxy acrylate-based polymers.

The fourth passivation layer 198 may preferably be a polymer that is curable. The fourth passivation layer 198 may also be formed by applying an additive such as a resin additive or an inorganic filler to improve performance.

The fourth passivation layer 198 may be formed to have a thickness of 500 nm to 4 μm by using a solution process.

Hereinafter, experiments and results of a transparent film according to an example and a comparative example of the present invention will be described.

In the embodiment of the present invention, the transparent film 100 includes a first hard coating layer 110, a base layer 120, a second hard coating layer 130, and a first refractive index matching layer 140, a first inorganic material layer 150, a metal layer 160, second inorganic material layer 170, a second refractive index matching layer 180, a first passivation layer 192, a second passivation layer 194, a third passivation layer 196, and a fourth passivation layer 198.

In an exemplary embodiment of the present invention, the first hard coating layer 110 and the second hard coating layer 130 were formed to have a thickness of 3 μm, and the base layer 120 was formed to have a thickness of 100 μm using PET. The first refractive index matching layer 140 was formed of Nb₂O₅ to have a thickness of 35 nm, the first inorganic material layer 150 and the second inorganic material layer 170 were formed of CuNx to have a thickness of 5 nm, and the metal layer 160 was formed of silver (Ag) to have a thickness of 10 nm. The second refractive index matching layer 180 was formed of Nb₂O₅ to have a thickness of 35 nm, the first passivation layer 192 was formed of PMMA to a thickness of 100 nm, the second passivation layer 194 was formed of epoxy acrylate to have a thickness of 180 nm, the third passivation layer 196 was formed of PMMA to have a thickness of 80 nm, and the fourth passivation layer 198 was formed of urethane acrylate to have a thickness of 1.5 μm.

In Comparative Example 1, the transparent film is formed to include a first hard coating layer, a base layer, a second hard coating layer, a refractive index matching layer, and a metal layer.

In Comparative Example 1, the first hard coating layer and the second hard coating layer were formed to have a thickness of 3 μm, and the base layer was formed to a thickness of 100 μm using PET. The first refractive index matching layer was formed of Nb₂O₅ to have a thickness of 35 nm, and the metal layer was formed of silver (Ag) to have a thickness of 10 nm.

In Comparative Example 2, the transparent film is formed to include a first hard coating layer, a base layer, a second hard coating layer, a refractive index matching layer, a first inorganic material layer, a metal layer, a second inorganic material layer, and a second refractive index matching layer.

In Comparative Example 2, the first hard coating layer and the second hard coating layer were formed to have a thickness of 3 μm, and the base layer was formed to a thickness of 100 μm using PET. The first refractive index matching layer was formed of Nb₂O₅ to have a thickness of 35 nm, the first inorganic material layer and the second inorganic material layer were formed of CuNx to have a thickness of 5 nm, the metal layer was formed of silver (Ag) to have a thickness of 10 nm, and the second refractive index matching layer was formed of Nb₂O₅ to have a thickness of 35 nm.

In Comparative Example 1, compared to an example of the present invention, there is a condition that neither the inorganic layer nor the organic layer for protecting the metal layer exists, and conditions (material and thickness) of other components are the same.

Comparative Example 2 constitutes only an inorganic layer for protecting the metal layer and does not constitute an organic layer, and the conditions (material and thickness) of other components are the same as compared to the example of the present invention.

[Table 2] shows luminance Y and transmittance at a wavelength of 550 nm.

TABLE 2

| | | Compare | Compare | Example of the |
|---|---|---|---|---|
| Evaluation item | | Example 1 | Example 2 | present invention |
| Transmittance | Y | 65.4 | 77.3 | 88.1 |
| | @ 550 nm | 76.9 | 77.6 | 88.4 |

Herein, Y indicates average transmittance, and @ 550 nm indicates transmittance at a wavelength of 550 nm.

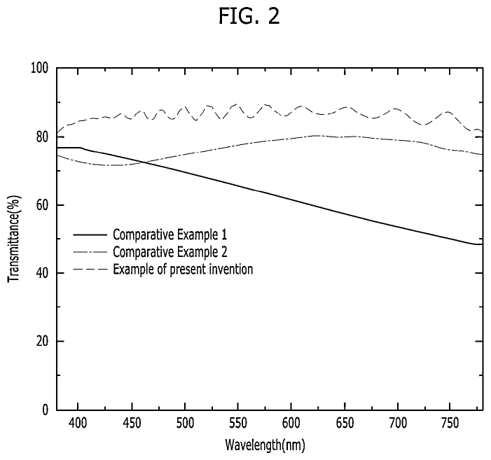

The transmittance depending on a wavelength in a visible ray region is the same as in FIG. 2. In Comparative Example 1, the transmittance was lower as the wavelength increased, and in Comparative Example 2, the transmittance was relatively high as it got closer to the infrared rays, but there was also a region in which the transmittance was rather low in the short wavelength region.

In contrast, in the example of the present invention, a high transmittance was shown over the entire visible ray region, which was superior to the comparative examples in terms of transmittance.

Table 3 shows comparison of before and after performances of Examples of the present invention, Comparative Examples 1 and 2 under high temperature and high humidity conditions, respectively.

Experiments were performed to measure the optical properties before and after 3,000 hours had elapsed under a temperature of 60° C. and a humidity of 90% (RH).

TABLE 3

| | | | | | | Example of | |
|---|---|---|---|---|---|---|---|
| | | Compare | | Compare | | the present | |
| | | Example 1 | | Example 2 | | invention | |
| Evaluation item | | Before | After | Before | After | Before | After |
| Trans- | Y | 65.4 | 72.7 | 77.6 | 78.6 | 88.1 | 88.4 |
| mittance | @ 550 nm | 65.6 | 73.2 | 77.6 | 79.5 | 87.2 | 89.4 |

As a result of the experiment, the transmittance was significantly higher in the example of the present invention compared to Comparative Examples 1 and 2.

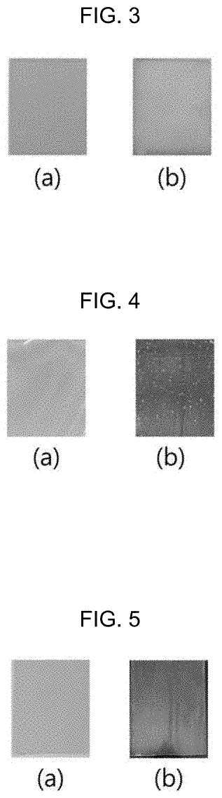

FIG. 3A illustrates a photograph before the experiment of Comparative Example 1, and FIG. 3B illustrates a photograph after the experiment of Comparative Example 1.

FIG. 4A illustrates a photograph before the experiment of Comparative Example 2, and FIG. 4B illustrates a photograph after the experiment of Comparative Example 2.

FIG. 5A illustrates a photograph before the experiment of the example of the present invention, and FIG. 5B illustrates a photograph after the experiment of the example of the present invention.

On the other hand, FIG. 4B and FIG. 5B illustrate photographs taken after a blackboard is provided at a back side in order to more clearly check a change in appearance

In the case of Comparative Example 1, the film color changed within 24 hours, and the change in transmittance as well as the change in appearance change was large, indicating that the change in performance before and after the reliability test was large.

In the case of Comparative Example 2, although reliability was somewhat improved by a function of the inorganic material layer, a change in appearance on which a spot occurred was observed.

In contrast, in the example of the present invention, it can be seen that a change in transmittance and color hardly occurred, so that the reliability was greatly improved compared to the comparative examples.

A water vapor transmission rate (WVTR) of the transparent film according to the example of the present invention was measured, and a water vapor transmission rate with the transparent film according to Comparative Example 1 was compared. Moisture has greatest effect on oxidation of metal layer, and comparison of a degree of passing of aqueous vapor may be a measure of reliability.

TABLE 4

| | Comparative | Example of the |
|---|---|---|
| | Example 1 | present invention |
| Water vapor | 5200 | 210 |
| transmission rate | | |
| (mg/m² · day) | | |

[Table 4] compares the water vapor transmission rate of the example and Comparative Example 1 of the present invention.

As a result of the experiment on the water vapor transmission rate, it was seen that the water vapor transmission rate in Comparative Example 1 was 5,200 mg/m2·day, and the water vapor transmission rate in the example of the present invention was measured to be mg/m2·day to reduce the water vapor transmission rate to a 1/25 level compared to Comparative Example 1 of the present invention.

As a result, according to the transparent film of the embodiment of the present invention, there is an effect of lowering the water vapor transmission rate, thereby improving reliability under high temperature and high humidity conditions.

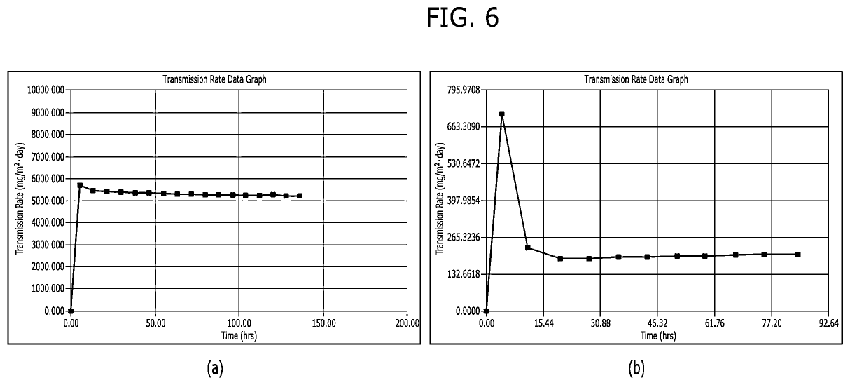

A measurement result of the water vapor transmission rate according to time is shown in FIG. 6.

Shielding performance against electromagnetic interference (EMI) of the transparent film according to an exemplary embodiment of the present invention was measured.

An experiment measured the shielding performance in dB in a frequency range of 30 MHz-1000 MHz.

As a result of the experiment, it was found that an electromagnetic wave was reduced by about 30 dB in the example of the present invention. This is lower than the ITO film by about 10 dB.

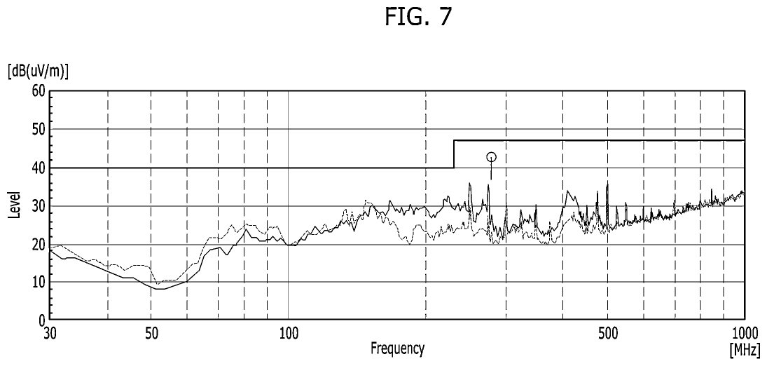

A level of noise jamming depending on a frequency is shown in FIG. 7.

Finally, the heat shielding performance of the transparent film according to the exemplary embodiment of the present invention was evaluated. The example of the present invention was compared with an indium tin oxide (ITO) film and silver nanowire (AgNWs) film.

In Comparative Example 3, the transparent film is formed to include a first hard coating layer, a base layer, a second hard coating layer, a refractive index matching layer, and an ITO layer.

In Comparative Example 4, the transparent film is formed to include a first hard coating layer, a base layer, a second hard coating layer, a refractive index matching layer, and a silver nanowire layer.

A heat shielding experiment was conducted in such a way that a heat source of 70° C. was prepared, and then a first surface of the transparent film in each example and the heat source were facing each other, and an infrared ray IR was positioned on a second surface thereof to measure a temperature.

In the example of the present invention, the temperature of the transparent film was measured to be 35.4° C. on the second surface, so it was found that the heat shielding performance was very excellent.

In contrast, in Comparative Example 3, the temperature of the transparent film was measured to be 69.6° C. on the second surface, showing a change was insignificant, and in Comparative Example 4, the temperature of the transparent film was measured to be 65.5° C. on the second surface, showing that the heat shielding performance was present, but it was found to be insignificant compared to the example of the present invention.

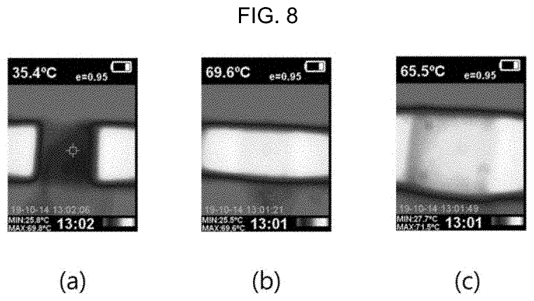

FIG. 8A illustrates an infrared-shooting photograph for evaluating the thermal insulation performance of the transparent film of the example of the present invention.

FIG. 8B illustrates an infrared-shooting photograph to evaluate the thermal insulation performance of the transparent film of Comparative Example 3.

FIG. 8C illustrates an infrared-shooting photograph to evaluate the thermal insulation performance of the transparent film of Comparative Example 4.

It is also to be understood that the terminology used herein is only for the purpose of describing particular embodiments, and is not intended to be limiting of the invention. It will be further understood that terms “comprise” or “have” used in the present specification specifies the presence of stated features, numerals, steps, operations, components, parts, or a combination thereof, but does not preclude the presence or addition of one or more other features, numerals, steps, operations, components, parts, or a combination thereof.

### DESCRIPTION OF SYMBOLS

100: Transparent film with enhanced durability
110: first hard coating layer
120: base layer
130: second hard coating layer
140: first refractive index matching layer
150: first inorganic material layer
160: metal layer
170: second inorganic material layer
180: second refractive index matching layer
192: first passivation layer
194: second passivation layer
196: third passivation layer
198: fourth passivation layer

What is claimed is:

1. A transparent film with enhanced durability, comprising:
a base layer;
a first inorganic material layer stacked on a first surface of the base layer;
a metal layer stacked on a first surface of the first inorganic material layer;
a second inorganic material layer stacked on a a first surface of the metal layer; and
a passivation layer configured to include a plurality of organic material layers stacked on a first surface of the second inorganic material layer.

2. The transparent film of claim 1, further comprising
a hard coating layer disposed on opposite surfaces of the base layer.

3. The transparent film of claim 1, further comprising
a refractive index matching layer disposed between the base layer and the first inorganic material layer and between the second inorganic material layer and the passivation layer, to reinforce a refractive index.

4. The transparent film of claim 1, wherein
the passivation layer includes:
a first passivation layer configured to include a first organic material;
a second passivation layer configured to include a second organic material;
a third passivation layer configured to include a third organic material; and
a fourth passivation layer configured to include a fourth an organic material.

5. The transparent film of claim 1, wherein
the metal layer includes silver (Ag), and
the first inorganic material layer and the second inorganic material layer include a copper oxide (CuOₓ).

6. The transparent film of claim 1, wherein
the metal layer includes silver (Ag), and
the first inorganic material layer and the second inorganic material layer include a copper nitride (CuNₓ).
